(19) United States
(12) Patent Application Publication
(10) Pub. No.: US 2003/0230818 A1
(43) Pub. Date: Dec. 18, 2003

(54) Micelle encapsulation of particle containing liquid droplets

(75) Inventors: Naveen Chopra, Oakville (CA); Peter M. Kazmaier, Mississauga (CA); Paul F. Smith, Oakville (CA); Paul J. Gerroir, Oakville (CA)

Correspondence Address: Patent Documentation Center, Xerox Corporation, Xerox Square 20th Floor, 100 Clinton Ave. S., Rochester, NY, 14644, US

(73) Assignee: Xerox Corporation

(21) Appl. No.: 10/175,587

(22) Filed: Jun. 18, 2002

(51) Int. Cl. G03F 5/00

(52) U.S. Cl. 264/4; 359/893

(57) ABSTRACT

A composition composed of a plurality of microcapsules each including a polymerized, optionally hardened, micelle shell encapsulating a liquid droplet and a particle component.

### BACKGROUND OF THE INVENTION

Microcapsules have a variety of uses. Various microencapsulation techniques are available to fabricate these microcapsules. New microcapsules and microencapsulation techniques are desired to expand the applications in which microencapsulation technology may be useful.

Conventional microcapsules and microencapsulation techniques are described in “Kirk-Othmer Encyclopedia of Chemical Technology,” Vol. 15, pp. 470-493 (3^{rd} Edition 1981); Speiser et al., U.S. Pat. No. 4,021,364; Nikles et al., U.S. Pat. No. 4,937,119; and Mullen, U.S. Pat. No. 5,824,337.

The present microcapsules and microencapsulation technique involve micelle encapsulation of particle containing liquid droplets. Micelles and amphiphiles are described in Nair et al., U.S. Pat. No. 5,429,826; Klaveness et al., U.S. Pat. No. 5,536,490; Klaveness et al., U.S. Pat. No. 6,106,806; David F. O'Brien et al., “Polymerization of Preformed Self-Organized Assemblies,” ACC. CHEM. RES. Vol. 31, pp. 861-868 (1998); and Mark Summers et al., “Polymerization of Cationic Surfactant Phases” Vol.17 LANGMUIR pp. 5388-5397 (2001).

The present microcapsules and microencapsulation technique may be used in the manufacture of components for display devices. Conventional display devices (some including microcapsules), components for display devices, and the manufacture of such display devices and their components are described in Sheridon, U.S. Pat. No. 5,604,027; Jacobson et al., U.S. Pat. No. 5,961,804; Jacobson et al., U.S. Pat. No. 5,930,026; Albert et al., U.S. Pat. No. 6,067,185; Crowley et al., U.S. Pat. No. 5,262,098; Sheridon, U.S. Pat. No. 5,344,594; and Stefik, U.S. Pat. No. 5,723,204.

### SUMMARY OF THE INVENTION

The present invention is accomplished in embodiments by providing an encapsulation process comprising:

(a) creating a heterogeneous mixture comprised of: (i) a continuous phase comprising a first liquid; and (ii) a disperse phase comprising a plurality of particle containing droplets including a second liquid and a particle component, wherein the second liquid is immiscible with the first liquid, thereby resulting in an interface between each of the droplets and the first liquid;

(b) adding an amphiphile prior to or during formation of the heterogeneous mixture to minimize re-association of the droplets, wherein the molecules of the amphiphile spontaneously orient around each of the droplets at the interface to form a micelle shell around each of the particle containing droplets; and

(c) polymerizing the micelle shell to form a polymerized micelle shell.

In additional embodiments, there is also provided a composition comprising: a plurality of microcapsules each including a polymerized, optionally hardened, micelle shell encapsulating a liquid droplet and a particle component.

In other embodiments, there is provided a display device comprising:

(a) a plurality of microcapsules each including a polymerized, optionally hardened, micelle shell encapsulating a single bichromal ball in a liquid droplet, the ball having two hemispheric surfaces, one surface differing from the other surface in both color and electrical characteristics, and wherein the color of the bichromal ball is discernable through the shell and the liquid droplet; and

(b) a substrate to receive the microcapsules.

### BRIEF DESCRIPTION OF THE DRAWINGS

Other aspects of the present invention will become apparent as the following description proceeds and upon reference to the Figures which represent illustrative embodiments:

FIG. 1 is a simplified illustration depicting an embodiment of the heterogeneous mixture including a plurality of capsules resulting from the encapsulation process, each capsule including a micelle shell encapsulating a liquid droplet with a particle component or a liquid droplet without a particle component; and

FIG. 2 is a simplified illustration depicting an embodiment of a display device composed of a plurality of microcapules and a substrate.

Unless otherwise noted, the same reference numeral in different Figures refers to the same or similar feature.

### DETAILED DESCRIPTION

The term microcapsules refers to small capsules having a size ranging for example from about 1 micrometer to about 2,000 micrometers.

The term shell refers to a wall providing the encapsulation; unless otherwise noted, the term shell by itself does not indicate the degree of toughness or hardness of the shell.

The phrase room temperature refers to a temperature of about 25 degrees C.

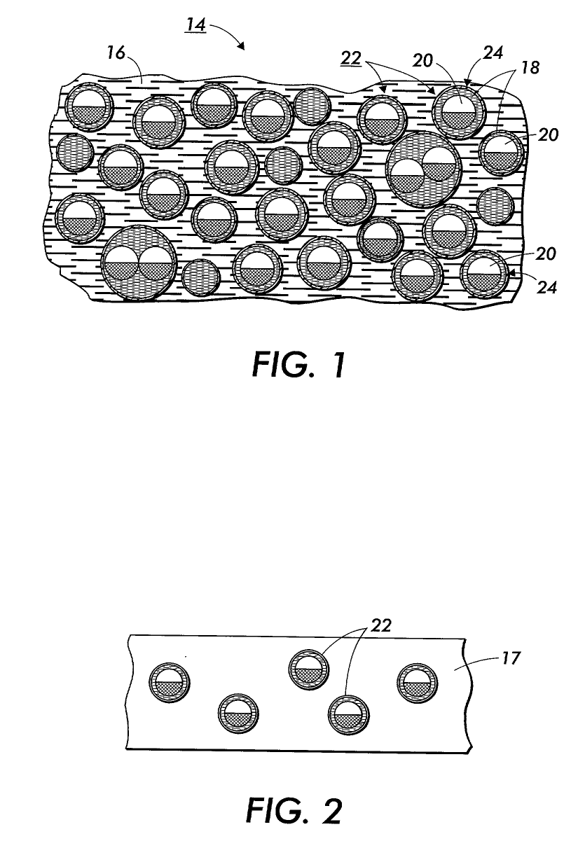

As seen in FIG. 1, the encapsulation process involves creating a heterogeneous mixture 14 comprised of: (i) a continuous phase 16 comprising a first liquid; and (ii) a disperse phase comprising a plurality of particle containing droplets 18 including a second liquid and a particle component 20, wherein the second liquid is immiscible with the first liquid, thereby resulting in an interface between each of the droplets and the first liquid.

Creation of the heterogeneous mixture may be accomplished in embodiments by creating a dispersion including the second liquid and a plurality of particles and then mixing the dispersion with the first liquid. In embodiments, one can add the dry particles to the first liquid (e.g., an aqueous composition) followed by addition of the second liquid (e.g., an organic liquid).

An amphiphile is added prior to or during formation of the heterogeneous mixture to minimize re-association of the droplets, wherein the molecules of the amphiphile spontaneously orient around each of the droplets at the interface to form a micelle shell 24 around each of the particle containing droplets, thereby resulting in a plurality of capsules 22. The amphiphile may be added at any suitable point. For example, the amphiphile can be added to the first liquid and/or the second liquid prior to their use in the encapsulation process. Also, the amphiphile can be added during the formation of the heterogeneous mixture such as during mixing of the dispersion (composed of the second liquid and the particles) with the first liquid. In one embodiment, the amphiphile can be added to the second liquid prior to the creating the dispersion including the second liquid and the particles.

Agitation may be used in the heterogeneous mixture. The agitation time ranges for example from about 1 minute to about 30 minutes, particularly from about 5 minutes to about 20 minutes. The agitation speed ranges for example from about 200 rpm to about 1,500 rpm, particularly from about 400 rpm to about 1,000 rpm. Any suitable equipment may be used for agitation including for instance a 3-bladed impeller.

In embodiments, an elevated temperature (i.e., a temperature above a room temperature of about 25 degrees C.) may be used to form the heterogeneous mixture such as a temperature ranging for example from about 40 to about 80 degrees C., particularly from about 50 to about 60 degrees C.

The various materials used to create the heterogeneous mixture can be employed in the following illustrative amounts by weight:

amphiphile to first liquid ratio: about 1 (amphiphile):1,000 (first liquid) to about 1:20;

second liquid (no suspended particles) to first liquid (continuous phase) ratio: about 1:1 to about 1:5; and

percent solids (i.e., suspended particles) in second liquid: about 5% to about 50% by weight.

It is difficult to ensure that all of the droplets in the heterogeneous mixture contain the same number of particles. Typically, the distribution number of particles within the droplets will be a continuum. The desired number of particles in each droplet may be for example 1, 2, 3, 4, 5, or more particles. If the desired number of particles is for example a single particle within a droplet, a distribution may result where a first group of droplets has 0 particles contained therein, a second group of droplets has 1 particle contained therein, possibly a third group of droplets has 2 particles contained therein, possibly a fourth group of droplets will have 3 particles contained therein, and the like. The formation of the heterogeneous mixture results in for example at least about 20% of the droplets containing particles of the desired number, about 20% to about 80% of the droplets containing particles of the desired number, and particularly a majority of the droplets containing particles of the desired number. In embodiments, forming the heterogeneous mixture results in a majority of the droplets having the single particle.

To increase the likelihood that a majority of the droplets contain only a single particle during formation of the heterogeneous mixture, exemplary procedures are described in the examples. The following parameters are illustrative to increase the likelihood that a majority of the droplets contain only a single particle during formation of the heterogeneous mixture: an agitation speed ranging from about 650 rpm to about 1,000 rpm (using for example a 3-bladed impeller); a flow rate of adding the second liquid (containing suspended particles) ranging from about 2 grams per minute to about 30 grams per minute, particularly from about 9 grams per minute to about 12 grams per minute; percent solids (by weight) of suspended particles in second liquid (values for second liquid are without suspended particles) ranging from about 1 g/24 g to about 15 g/24 g, particularly, from about 8 g/24 g to about 12 g/24 g; and ratio (vol:vol) of second liquid (no particles) to first liquid ranging from about 10 ml:230 ml to about 100 ml:230 ml, particularly from about 20 ml:230 ml to about 50 ml:230 ml.

For other desired particle numbers such as two, three, four, five, and the like, it is believed that a majority of the droplets containing the desired particle number can be created by trial and error in selecting the values for the various heterogeneous mixture formation parameters. These heterogeneous mixture formation parameters include for instance the following: mixer speed in rpm, flow rate of adding the second liquid (containing suspended particles), percent solids (i.e., suspended particles) in second liquid, and second liquid (no suspended particles) to first liquid ratio.

Using any suitable method and materials, the micelle shell is polymerized to form a polymerized micelle shell. One illustrative method is free radical polymerization. This can be achieved by different means. Photopolymerization can be achieved by for example UV irradiation (e.g., at 254 nm using a xenon lamp), with irradiation times ranging from minutes to several hours time. Free radical polymerization can be achieved thermally for instance by the addition of a free radical initiator such as AIBN (azobisisobutyronitrile). Other initiators include benzoyl peroxide, and VAZO compounds, available from DuPont. VAZO compounds are structural analogs of AIBN, with different degrees of activity. See http://www.dupont.com/vazo/overview.html. The amount of initiator used can range from about 0.1 to 100% of the molar quantity of the reacting material. Typical dosages are from about 0.12 mmol to about 1.2 mmol of initiator per 2 mmol of reacting material (about 10-60%). More information on other polymerization techniques are described in Klaveness et al., U.S. Pat. No. 5,536,490, column 12, lines 26 to 51.

The first liquid or the second liquid may be for instance an aqueous composition including solely water or an aqueous mixture composed of water and one or more other water miscible fluids such as for example an alcohol like methanol and ethanol. In the aqueous mixture, water may be present in an amount ranging for example from about 20% to about 80% by volume, the balance of the volume being the one or more water miscible fluids.

The first liquid or the second liquid may be for example an organic fluid. General classes include for example: (1) linear or branched aliphatic hydrocarbons (e.g., ISOPAR™); (2) halogenated hydrocarbons (e.g., chloroform, 1,2-dichloroethylene); (3) aromatic hydrocarbons (e.g., benzene and toluene); and low molecular weight polymers such as silicone oils like polydimethylsiloxanes (e.g., Dow Corning 200® fluid). Suitable materials for the first liquid or second liquid include those described in U.S. Pat. No. 6,067,185, the disclosure of which is totally incorporated herein by reference.

Any suitable materials may be employed for the first liquid and the second liquid as long as the second liquid is immiscible with the first liquid to the extent that droplets of the second liquid are formed in the heterogeneous mixture. In embodiments, the first liquid is an aqueous composition and the second liquid is an organic liquid; in other embodiments, the first liquid is an organic liquid and the second liquid is an aqueous composition.

Examples of amphiphiles suitable for use in the present invention are disclosed in Klaveness et al., U.S. Pat. No. 5,536,490 and Klaveness et al., U.S. Pat. No. 6,106,806, the disclosures of which are totally incorporated herein by reference. In these patents, for instance, they describe polymerized micelle shells. In U.S. Pat. No. 5,536,490, columns 13-15, there are described example 2 (bis-(trieicoso-10,12-diynoyl)phosphatidyl choline), example 5 (tetraethylene glycol mono-12-(methacryloyloxy)dodecanoate), and example 8b (tetraethylene glycol mono-16-(methacryloyloxy)hexadecanoate). Many other examples are given in these patents such as monomeric amphiphiles including cyanoacrylate esters carrying lipophilic esterifying groups (which may also have hydrophilic moieties). In general, these polymerizable amphiphiles have unsaturated sites on the lipophilic chains (double and triple bonds) that can react with one another. Functional groups such as: oleyl, linoleyl, styryl, acetylenes, acryloyl, methacrolyl are examples of polymerizable hydrophobic groups. The head groups (hydrophilic) can be crosslinked in various ways. Amino terminated groups can be crosslinked with a difunctional group, such as a dicarboxylic acid, or dialdehyde such as gluteraldehyde. Alcohol terminated head groups can be crosslinked with diacid chlorides. Or, in either case, the polar head groups can be capped with a preformed polymer such as the aminoplasts (urea-formaldehyde prepolymer).

Particular amphiphiles with polymerizable reactive sites and/or reactive groups include for example the structures of polymerizable amphiphiles described in Klaveness et al., U.S. Pat. No. 5,536,490 column 7, line 22 to column 11, line 44. For example, there are disclosed phospholipids such as phosphodiglycerides and sphingolipids carrying polymerizable groups, phosphatidyl ethanoamine-type molecules endowed with alkyl chains bearing alternate double and triple bonds (column 7, lines 23-30).

The particles may be composed of any suitable material, where the composition of the particles depends upon their intended use. The particles can play a role in for example electronic display devices, carbonless copy paper systems, cosmetics, paints, adhesives, pesticides, pharmaceuticals, and other fields not specifically listed herein. In embodiments, the particles are free to move in response to an applied field such as an electric field or a magnetic field. To allow movement of the one or more particles within the microcapsule in response to the applied field, the one or more particles are spaced from the inner surface of the shell. In embodiments, each particle may exhibit one, two, three or more colors.

In embodiments, the particles are used in electronic display devices where the particles are for example hemispheric bichromal balls which have an optical and an electrical anisotropy due to each hemisphere surface having a different color (e.g., one hemisphere is white and the other hemisphere is black) and electrical charge. The bichromal balls are free to rotate within the microcapsules in response to an applied electrical field. The bichromal balls are composed of the following illustrative materials: as the matrix, a polarizable material such as a polymer or a wax like polyethylene wax may be used; the white pigment may be titanium dioxide; and the black pigment may be magnetite (Fe₂O₃) or carbon black. Bichromal balls and their fabrication are described in U.S. Pat. Nos. 5,262,098; 5,344,594; and 5,604,027, the disclosures of which are totally incorporated herein by reference. In other embodiments, the bichromal balls can be made with magnetic anisotropy so that they are free to rotate within the microcapsules in response to an applied magnetic field.

The micelle shell is optionally hardened. This hardening may be accomplished by for example thermal treatment, desolvation techniques, crosslinking, polymerization and the like. In embodiments, a hardening approach involves crosslinking of the head groups or tail groups, or both head groups and tail groups, of the amphiphiles forming the micelle shell. In embodiments, only the groups facing outward from the micelle shell (either head groups or tail groups) are crosslinked. In general, the head group of the amphiphiles can be for example an amine, or a zwitterionic type like phosphatidyl choline, ethanolamine, serine, or glycerol (see Klaveness et al. U.S. Pat. No. 5,536,490, column 6, lines 16-20). Alternatively, one could have a 4-vinyl benzoate group associated with a quaternary amine head group (cetyltrimethylammonium 4-vinyl benzoate) This 4-vinyl benzoate group could be polymerized with UV light or free radical initiator (AIBN). See Mark Summers et al., “Polymerization of Cationic Surfactant Phases” Vol.17 LANGMUIR pp. 5388-5397 (2001).

One technique to harden the polymerized micelle shell is introducing a crosslinking agent into the heterogeneous mixture where the cross-linking agent reacts with the micelle shell. Typically, the crosslinking agent is an aldehyde. Tannin may also be used to harden the micelle shell. The aldehyde crosslinking agent may be for instance formaldehyde and glutaraldehyde. Other crosslinking agents include acroleine, glyoxal, and cinnamaldehyde. The crosslinking agent may be added in an amount ranging from about 0.1 to about 5 wt %, particularly from about 0.5 to about 1 wt %, based on the weight of the heterogeneous mixture.

In embodiments, the microcapsules containing the polymerized, optionally hardened, micelle shell are encapsulated with one or more additional shells. These one or more additional shells may be for instance another polymerized, optionally hardened, micelle shell, a simple coacervation indued shell, or a complex coacervation induced shell. In fact, any suitable encapsulation technique can be used to provide these one or more additional shells, which are optionally hardened, such as those encapsulation techniques described in “Kirk-Othmer Encyclopedia of Chemical Technology,” Vol. 15, pp. 470-493 (3^{rd} Edition 1981); Klaveness et al., U.S. Pat. No. 6,110,444; Jason et al., U.S. Pat. No. 5,540,927; Baker et al., U.S. Pat. No. 4,808,408, the disclosures of which are totally incorporated herein by reference.

Hardening of the micelle shell and/or encapsulating the polymerized micelle shell with another shell or shells may improve properties such as the mechanical resilience and/or biocompatibility of the microcapsules.

The encapsulation process may include recovering the microcapsules which involves separating them from the reaction mixture by techniques such as sedimentation, flotation or filtration involving for instance continuous or repeated washing.

Optionally, the present process further involves selecting microcapsules having the desired particle number. These microcapsules having the desired particle number may be separated and collected from the other microcapsules by any appropriate method including for example classifying according to size by using mesh screens, or classifying according to density by using a separation funnel. The recovered microcapsules may be stored as a suspension in an appropriate diluent or in dried powder form in for example a closed vessel under a chosen gas atmosphere. Appropriate diluents for stored suspensions or for reconstitution of dried forms include sterile water, physiological saline and biocompatible buffers, such as phosphate-buffered saline. Other diluents include for example organic fluids. Where the diluent is an organic fluid, general classes for the diluent include for example: (1) linear or branched aliphatic hydrocarbons (e.g., ISOPAR™); (2) halogenated hydrocarbons (e.g., chloroform, 1,2-dichoroethylene); (3) aromatic hydrocarbons (e.g., benzene and toluene); and low molecular weight polymers such as silicone oils like polydimethylsiloxanes (e.g., Dow Corning 200® fluid of appropriate molecular weight). Polydimethylsiloxane oils come in various types, and they are often categorized by their viscosities in centistokes (“cSt”). They are commercially available from Aldrich. 0.65 cSt Dow Coming 200® fluid has a molecular weight (“Mw”) of 162.38. 1 cSt Dow Coming 200® fluid has a Mw of 236.54. The Mw of 5 cSt Dow Coming 200® fluid is unknown.

The present microcapsules have continuous encapsulation and may have any suitable shape such as spherical, with a diameter ranging for example from about 10 micrometers to about 300 micrometers, particularly from about 50 micrometers to about 200 micrometers. The shell has a thickness ranging for example from about 0.5 micrometer to about 5 micrometers, particularly from about 1 micrometer to about 3 micrometers. The particles may be of any shape such as spherical or oblong. The particles have a diameter ranging for example from about 10 micrometers to about 100 micrometers, particularly from about 20 micrometers to about 60 micrometers. Other suitable dimensions for the microcapsules, shells, and particles may be used in embodiments of the present invention. The volume contained by the shell exceeds the volume of the one or more encapsulated particle(s) by an amount ranging for example from about 15% to about 2,600%, particularly from about 30% to about 700%, and especially from about 70% to about 250%. We arrive at these percentages by subtracting the volume of the one or more particle(s) from the volume contained by the shell, and then dividing by the volume of the one or more particle(s). For simplicity, these percentages are based on a spherical shell and spherical particle(s).

A preferred technique to measure the volume of the shell and of the particle(s) is visual observation with photographic image analysis, optical microscope, or scanning electron microscopy, determining for example the average values of three randomly chosen microcapsules. The use of electron microscopy can also be used to measure the thickness of capsule walls by freeze-fracturing the shell to obtain a cross-section of the wall material.

In embodiments of the present invention, the instant encapsulation process results in capsules where there is sufficient room within the capsules for the 1, 2, 3, 4, 5, or more particles to rotate, but the capsule volume occupied by the particle component is relatively large relative to the total capsule volume (i.e., volume bounded by the shell) such that one additional similarly-sized particle cannot fit within the capsule (see for example FIG. 1 where the volume of the capsules containing 1 or 2 particles is too small to accommodate one additional similarly-sized particle). Where the capsules contain particles of different sizes, the one additional particle is based on the dimensions of the largest particle within the capsule. Thus, in embodiments, the particle component contained within each of the microcapsules has a size such that no additional particle can fit within the microcapsule.

Advantages of the present invention where the volume of the shell and particle(s) is in the specified values include increased contrast and viewing area of the particle(s) (for the hemispheric bichromal balls) and increased packing efficiency of the microcapsules.

The present microcapsules may be useful in any situation where microcapsules may be advantageously employed. The present microcapsules may be useful for example in electronic display devices, carbonless copy paper systems, cosmetics, paints, adhesives, pesticides, pharmaceuticals, and other fields not specifically listed herein. One use of the present microcapsules is as visual indicators in for example a display device. Microcapsules as voltage sensitive members (i.e., where the particle or particles within the shell is movable in response to an applied field) will then indicate the voltage condition at their locations. When used in conjunction with an addressing means they can constitute an information display. Other uses might include the visualization or measurement of local electrical fields in test systems.

The present microcapsules may be dispersed into any suitable medium which may be a liquid, a solid, or a gas. When these microcapsules constitute voltage sensitive members, the microcapsules may be dispersed in any medium across which an electrical field may be impressed. Most commonly this medium will be a solid, with the microcapsules dispersed in this solid while it is in a liquid phase. It will be subsequently hardened by chemical reaction, by cooling, or the like. The medium may also be a liquid, or a slurry consisting of a liquid and solid particles, or solid particles whose purpose might be to immobilize the microcapsules. Indeed, any medium might be used to contain the microcapsules provided that it does not damage the shell of the microcapsule or diffuse undesirable chemicals across the shell.

The present invention allows the medium to be made for example from a large number of dielectric materials that are obtained by hardening a liquid phase of the material into which the microcapsules have been dispersed. In general, the shells will permit chemical isolation of the hardenable medium material from the fill (i.e., the liquid droplet and particle(s)) of the microcapsules, providing great freedom in choosing the medium. A particularly useful application of this technology is to mix the microcapsules with a transparent hardenable material, such as a varnish, and to paint or spray the resulting dispersion onto a surface, which may be nonplanar. In this way, one may not only obtain display surfaces that conform to objects of any shape, but one also obtains articles of decoration or camouflage. Simply applying electrical fields will cause such surfaces to change color, inexpensively. Useful surfaces include structural members and fabrics, especially articles of clothing. In addition to being dispersed in the liquid that is subsequently hardened, the microcapsules can also be adhered by adhesives that are coated onto surfaces, typically forming monolayers. Thus, for example, an article of clothing could be coated with an adhesive and subsequently microcapsules could be adhered to the adhesive. Thereafter the color of that article of clothing could be altered by the application of electrical fields. Likewise, the surface of an object that there is an intention to conceal could be coated with a monolayer of microcapsules and a spatially varying voltage could be applied to these microcapsules to control the pattern of color on the surface of that object.

FIG. 3 depicts an embodiment of a display device composed of a plurality of microcapsules 22 and a substrate 17. In embodiments, an adhesive may be present to bind the microcapsules to the substrate.

In applications of the microcapsules where it is advantageous to see the color of the particle component of the microcapsules, such as where the microcapsules are part of a display device, the shell (or shells) and the second liquid of the microcapsules may be sufficiently transparent and sufficiently colorless to discern the color or colors of the particle component. In embodiments, the shell (or shells) and the second liquid are clear and colorless.

The invention will now be described in detail with respect to specific embodiments thereof, it being understood that these examples are intended to be illustrative only and the invention is not intended to be limited to the materials, conditions, or process parameters recited herein. All percentages and parts are by weight unless otherwise indicated.

The Examples below are “paper examples.” In the Examples below, the impeller is a 3-blade impeller, overall diameter is 1¼ inch, each blade is 1/2 inch in width, and the pitch of the blades is 45 degrees. For Example 1 using a 600 ml beaker, the inner diameter of the beaker is 3½ inches, and the depth is 4½ inches. For Example 2, the Morton flask dimensions are: 500 ml capacity, on the walls are 4 baffles symmetrically situated, each 1¾ inches long, protruding 1/2 inch into the vessel, and 2½ inches from the top of the flask. The flask dimensions are: 4 inches inner diameter, and 4 inches in depth.

### EXAMPLE 1

(A Modification of Example 1 in U.S. Pat. No. 5,536,490)

A saturated solution of bis-linoleyl-lecithin (amphiphile) in an aqueous medium is obtained by mixing 100 mg of the amphiphile in 100 mL of deionized water. The saturated solution is filtered through a 0.45 micrometer filter. To this solution is added with stirring a 10 wt % suspension of hemispheric bichromal balls in ISOPAR™ M (a mixture of isoparaffinic hydrocarbons). The hemispheric bichromal balls have an optical and an electrical anisotropy due to each hemisphere surface having a different color (one hemisphere was white and the other hemisphere was black) and electrical charge. The bichromal balls have a size ranging from about 90 to about 106 micrometers and had a composition as described herein. During the stirring, micelle droplets of liquid (containing particles) in water are formed. The amphiphilic molecules at the oil/water interface are polymerized by UV irradiation of the suspension at 254 nm using a xenon lamp for 1 hour or by addition of about 20 mg AIBN (azobisisobutyronitrile) initiator. The resulting capsules that are formed (with polymerized micelle shells) can be subsequently hardened with a suitable crosslinking agent (such as urea-formaldehyde or melamine-formaldehyde). The resultant capsules are removed by filtration, and dried to furnish dry, free-flowing capsules. The majority of the capsules contain only a single bichromal ball.

### EXAMPLE 2

Repeat the procedures of Example 1, but use bis-(trieicoso-10,12-diynoyl) phosphatidyl choline in place of bis-linoleyl-lecithin.

### EXAMPLE 3

Repeat the procedures of Example 1. The resultant single shell capsules (with polymerized micelle shells) are subjected to a second microencapsulation process. In a warm water bath, equipped with a Morton flask and overhead stirrer, there is added 50 mL of 10 wt % gelatin warmed to 55 degrees C. Following this addition, 50 mL of warm deionized water is added. About 5 mL of 5 wt % sodium polyphosphate is added, then 20% volume/volume acetic acid is added dropwise to the solution, until a pH 4.3-4.7 to create a cloudy suspension of shell-forming coacervate media. The single shell capsules are added to the coacervate, and the suspension is allowed to cool gradually to room temperature. The dual shell capsules are washed, isolated, and freeze-dried to yield a dry free flowing powder.

### ADDITIONAL EXAMPLES

Repeat the procedures of Example 1, but use the amphiphiles prepared according to Examples 5-17 of U.S. Pat. No. 5,536,490. The disclosure of U.S. Pat. No. 5,536,490 is hereby totally incorporated herein by reference.

Other modifications of the present invention may occur to those skilled in the art based upon a reading of the present disclosure and these modifications are intended to be included within the scope of the present invention.

We claim:

1. An encapsulation process comprising:
(a) creating a heterogeneous mixture comprised of: (i) a continuous phase comprising a first liquid; and (ii) a disperse phase comprising a plurality of particle containing droplets including a second liquid and a particle component, wherein the second liquid is immiscible with the first liquid, thereby resulting in an interface between each of the droplets and the first liquid;
(b) adding an amphiphile prior to or during formation of the heterogeneous mixture to minimize re-association of the droplets, wherein the molecules of the amphiphile spontaneously orient around each of the droplets at the interface to form a micelle shell around each of the particle containing droplets; and
(c) polymerizing the micelle shell to form a polymerized micelle shell.

2. The process of claim 1, further comprising hardening the polymerized micelle shell.

3. The process of claim 1, wherein there results a plurality of particle containing microcapsules and wherein the particle component contained within each of the microcapsules has a size such that no additional particle can fit within the microcapsule.

4. The process of claim 1, wherein the creating the heterogeneous mixture is accomplished by creating a dispersion including the second liquid and a plurality of particles and then mixing the dispersion with the first liquid.

5. The process of claim 4, wherein the amphiphile is added to the second liquid prior to the creating the dispersion including the second liquid and the particles.

6. The process of claim 1, further comprising encapsulating the polymerized micelle shell with another shell.

7. The process of claim 1, wherein each of the particle containing droplets includes from one to five particles.

8. The process of claim 1, wherein each of the particle containing droplets includes a single particle.

9. The process of claim 1, wherein the particle component exhibits at least one color and the at least one color of the particle component is discernable through the shell and the second liquid.

10. The process of claim 1, wherein the first liquid is an aqueous composition and the second liquid is an organic liquid.

11. A composition comprising: a plurality of microcapsules each including a polymerized, optionally hardened, micelle shell encapsulating a liquid droplet and a particle component.

12. The composition of claim 11, wherein the plurality of microcapsules each further includes another shell encapsulating the micelle shell.

13. The composition of claim 11, wherein the particle component ranges from one to five particles.

14. The composition of claim 11, wherein the particle component is a single particle.

15. The composition of claim 11, wherein the particle component is a single bichromal ball having two hemispheric surfaces, one surface differing from the other surface in both color and electrical characteristics, and wherein the color of the bichromal ball is discernable through the shell and the liquid droplet.

16. The composition of claim 11, wherein the particle component contained within each of the microcapsules has a size such that no additional particle can fit within the microcapsule.

17. A display device comprising:
(a) a plurality of microcapsules each including a polymerized, optionally hardened, micelle shell encapsulating a single bichromal ball in a liquid droplet, the ball having two hemispheric surfaces, one surface differing from the other surface in both color and electrical characteristics, and wherein the color of the bichromal ball is discernable through the shell and the liquid droplet; and
(b) a substrate to receive the microcapsules.

18. The display device of claim 17, further comprising an adhesive to bind the microcapsules to the substrate.

19. The display device of claim 17, wherein the plurality of microcapsules each further includes another shell encapsulating the micelle shell, wherein the color of the bichromal ball is discernable through the another shell.

20. The display device of claim 17, wherein the particle component contained within each of the microcapsules has a size such that no additional particle can fit within the microcapsule.
